(19) United States
(12) Patent Application Publication
(10) Pub. No.: US 2026/0202141 A1
(43) Pub. Date: Jul. 16, 2026

(54) GRANULATED PARTICLE FOR COLD STORAGE PARTICLES, COLD STORAGE PARTICLES, REGENERATOR, REFRIGERATOR, CRYOPUMP, SUPERCONDUCTING MAGNET, NUCLEAR MAGNETIC RESONANCE IMAGING APPARATUS, NUCLEAR MAGNETIC RESONANCE APPARATUS, MAGNETIC FIELD APPLICATION-TYPE SINGLE CRYSTAL PULLING-OUT APPARATUS, AND HELIUM RECONDENSING APPARATUS

(71) Applicant: Niterra Materials Co., Ltd., Yokohama-shi (JP)

(72) Inventors: Takahiro KAWAMOTO, Kawasaki Kanagawa (JP); Koichi HARADA, Bunkyo Tokyo (JP); Masaya HAGIWARA, Yokohama Kanagawa (JP); Daichi USUI, Kawasaki Kanagawa (JP)

(73) Assignee: Niterra Materials Co., Ltd., Yokohama-shi (JP)

(21) Appl. No.: 19/562,436

(22) Filed: Mar. 10, 2026

Related U.S. Application Data
(63) Continuation of application No. PCT/JP2024/011110, filed on Mar. 21, 2024.

(30) Foreign Application Priority Data
Sep. 14, 2023 (JP) 2023-149071

(51) Int. Cl. F28D 20/00; F28D 21/00; G01R 33/38

(52) U.S. Cl. CPC F28D 20/0056; G01R 33/3804; F28D 2021/0028; F28D 2021/0033; F28D 2021/005; F28D 2021/0063

(57) ABSTRACT

A granulated particle for cold storage particles of an embodiment includes: a first region having a first void fraction; and a second region that is closer to an outer edge of the particle than the first region and has a second void fraction lower than the first void fraction.

### CROSS-REFERENCE TO RELATED APPLICATION

This application is continuation application of, and claims the benefit of priority from the International Application PCT/JP2024/011110, filed Mar. 21, 2024, which claims the benefit of priority from Japanese Patent Application No. 2023-149071, filed on Sep. 14, 2023, the entire contents of all of which are incorporated herein by reference.

### FIELD

Embodiments of the present invention relate to a granulated particle for cold storage particles, a cold storage particle, a regenerator, a refrigerator, a cryopump, a superconducting magnet, a nuclear magnetic resonance imaging apparatus, a nuclear magnetic resonance apparatus, a magnetic field application-type single crystal pulling-out apparatus, and a helium recondensing apparatus.

### BACKGROUND

In recent years, superconducting technologies have remarkably developed, and expansion of application fields of the superconducting technologies has led to an indispensable demand for development of small and high-performance cryogenic refrigerators. Cryogenic refrigerators need to be lightweight, compact, and highly thermally efficient. Cryogenic refrigerators have been put into practical use in various application fields.

A cryogenic refrigerator includes a regenerator filled with a plurality of cold storage materials. For example, cooling is performed by heat exchange between the cold storage materials and helium gas passing through the regenerator.

Examples of the cold storage materials include ceramic magnetic cold storage particles containing a rare-earth element. The ceramic magnetic cold storage particles are manufactured, for example, by sintering granulated particles obtained by gelling of raw material powders.

When the strength of the gelled granulated particles is low, for example, a problem arises in that the granulated particles are broken during conveyance before sintering. Hence, realization of granulated particles for cold storage particles having high mechanical strength is anticipated.

### BRIEF DESCRIPTION OF THE DRAWINGS

FIG. 1 is a schematic cross-sectional view of a granulated particle for cold storage particles according to a first embodiment.

FIG. 2 is a schematic cross-sectional view of a granulated particle for cold storage particles according to a modification example of the first embodiment.

FIG. 3 is a schematic cross-sectional view of a granulated particle for cold storage particles according to a second embodiment.

FIG. 4 is a schematic cross-sectional view illustrating a configuration of a main part of a refrigerator of a fifth embodiment.

FIG. 5 is a cross-sectional view illustrating a schematic configuration of a cryopump of a sixth embodiment.

FIG. 6 is a perspective view illustrating a schematic configuration of a superconducting magnet of a seventh embodiment.

FIG. 7 is a cross-sectional view illustrating a schematic configuration of a nuclear magnetic resonance imaging apparatus of an eighth embodiment.

FIG. 8 is a cross-sectional view illustrating a schematic configuration of a nuclear magnetic resonance apparatus of a ninth embodiment.

FIG. 9 is a perspective view illustrating a schematic configuration of a magnetic field application-type single crystal pulling-out apparatus of a tenth embodiment.

FIG. 10 is a schematic view illustrating a schematic configuration of a helium recondensing apparatus of an eleventh embodiment.

FIG. 11 is a graph illustrating evaluation results of examples and a comparative example.

### DETAILED DESCRIPTION

A granulated particle for cold storage particles of an embodiment includes: a first region having a first void fraction; and a second region that is closer to an outer edge of the particle than the first region and has a second void fraction lower than the first void fraction.

Hereinafter, embodiments of the present invention will be described with reference to the drawings. In the following description, the same or similar members and the like are denoted by the same reference numerals, and the description of the members and the like which have been described once may be appropriately omitted.

In the present specification, a cryogenic temperature is, for example, a temperature range in which a superconducting phenomenon can be industrially used. The cryogenic temperature is, for example, in a temperature range of 20 K or lower.

### First Embodiment

A granulated particle for cold storage particles of a first embodiment includes: a first region having a first void fraction; and a second region that is closer to an outer edge of the particle than the first region and has a second void fraction lower than the first void fraction.

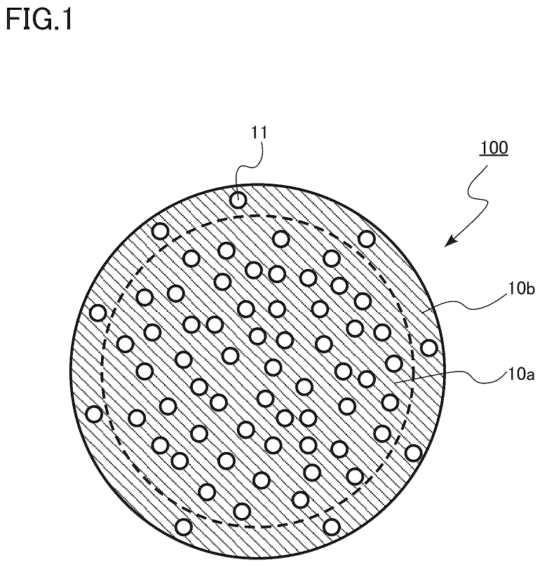

FIG. 1 is a schematic cross-sectional view of the granulated particle for cold storage particles according to the first embodiment.

A granulated particle 100 for cold storage particles of the first embodiment is a granulated particle for manufacturing the cold storage particles. The granulated particle 100 for cold storage particles is, for example, a granulated particle for manufacturing ceramic magnetic cold storage particles.

For example, the granulated particle 100 for cold storage particles of the first embodiment is subjected to a heat treatment for sintering, and thereby the cold storage particles are manufactured. Before the heat treatment for sintering, for example, the granulated particle 100 for cold storage particles may be subjected to a heat treatment for sulfurization.

As illustrated in FIG. 1, the granulated particle 100 for cold storage particles includes a first region 10a and a second region 10b. In addition, the granulated particle 100 for cold storage particles includes voids 11. Air is contained in the voids 11, for example.

The granulated particle 100 for cold storage particles includes, for example, at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu); and oxygen (O).

The granulated particle 100 for cold storage particles is an aggregate of raw material powders. The granulated particle 100 for cold storage particles is formed by granulating the raw material powders.

The granulated particle 100 for cold storage particles is a gel, for example. The granulated particle 100 for cold storage particles is formed by, for example, gelling a plurality of raw material powders by using a gelling agent (gelling solution). For example, the raw material powders lose independent mobility and are aggregated and solidified.

In a case where the granulated particle 100 for cold storage particles is a gel, the granulated particle 100 for cold storage particles includes, for example, raw material powders and a dispersion medium. The dispersion medium contains, for example, a gelling agent. In a case where the granulated particle 100 for cold storage particles is a gel, the granulated particle 100 for cold storage particles includes, for example, the raw material powders and the gelling agent. A gelling agent having gelled after gelling of the granulated particle 100 for cold storage particles is also referred to as the gelling agent.

The raw material powders contain, for example, a rare-earth oxysulfide or a rare-earth oxide. The rare-earth oxysulfide contained in the raw material powders contains at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). In addition, the rare-earth oxide contained in the raw material powders contains at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

The rare-earth oxysulfide contained in the raw material powders is, for example, gadolinium oxysulfide, terbium oxysulfide, dysprosium oxysulfide, or holmium oxysulfide. The rare-earth oxysulfide contained in the raw material powder is, for example, Gd₂O₂S, Tb₂O₂S, Dy₂O₂S, Ho₂O₂S, or Er₂O₂S.

The rare-earth oxide contained in the raw material powders is, for example, gadolinium oxide, terbium oxide, dysprosium oxide, or holmium oxide. The rare-earth oxide contained in the raw material powders is, for example, Gd₂O₃, Tb₂O₃, Dy₂O₃, Ho₂O₃, or Er₂O₃.

Composition analysis of the raw material powders can be performed by, for example, energy dispersive X-ray spectroscopy (EDX) or wave dispersive spectroscopy (WDX). In addition, substances of the raw material powders can be identified by, for example, powder X-ray diffraction.

The granulated particle 100 for cold storage particles contains, for example, an additional metal. The additional metal is, for example, one metal element selected from the group consisting of calcium (Ca), magnesium (Mg), beryllium (Be), strontium (Sr), aluminum (Al), iron (Fe), copper (Cu), nickel (Ni), and cobalt (Co). The additional metal is derived from, for example, a gelling solution used in manufacturing the granulated particle 100 for cold storage particles.

Detection of an element contained in the granulated particle 100 for cold storage particles and measurement of an atomic concentration of the element can be performed by using, for example, inductively coupled plasma atomic emission spectroscopy (ICP-AES). In addition, it is also possible to use the energy dispersive X-ray spectroscopy (EDX) or the wave dispersive spectroscopy (WDX).

A relative density of the granulated particle 100 for cold storage particles is, for example, equal to or higher than 10% and equal to or lower than 50%.

For example, in a case where the relative density of the granulated particle 100 for cold storage particles is low, a volume percentage of the raw material powders in the granulated particle 100 for cold storage particles is relatively low. In a case where the relative density of the granulated particle 100 for cold storage particles is low, a volume percentage of the dispersion medium or the voids 11 in the granulated particle 100 for cold storage particles is relatively high.

On the other hand, in a case where the relative density of the granulated particle 100 for cold storage particles is high, the volume percentage of the raw material powders in the granulated particle 100 for cold storage particles is relatively high. In a case where the relative density of the granulated particle 100 for cold storage particles is high, the volume percentage of the dispersion medium or the voids 11 in the granulated particle 100 for cold storage particles is relatively low.

The granulated particle 100 for cold storage particles is baked and biscuit-fired to form cold storage particles. Therefore, the relative density of the cold storage particles is higher than that of the granulated particle for cold storage particles.

The relative density of the granulated particle 100 for cold storage particles can be calculated, for example, by dividing an average molding density obtained from 50 randomly selected grains of the granulated particles for cold storage particles by a true density of constituent materials. The average molding density of the 50 grains is obtained by dividing a weight of the 50 grains of the granulated particles for cold storage particles by a volume. The volume can be calculated by integrating volumes of individual particles obtained by assuming an equivalent circle diameter of the particles as a diameter of the particles.

In the calculation of the true density of the granulated particle 100 for cold storage particles, first, a crystal phase of the raw material powders constituting the granulated particle is identified by X-ray diffraction measurement. Then, a component ratio of the raw material powders constituting the granulated particle is obtained from Rietveld analysis or inductively coupled plasma atomic emission spectroscopy of an X-ray diffraction pattern. The true density of the granulated particle 100 for cold storage particles can be calculated from the crystal phase of the raw material powders and the component ratio of the raw material powders.

A particle size of the granulated particle 100 for cold storage particles is, for example, equal to or larger than 50 μm and equal to or smaller than 7 mm. In addition, an aspect ratio of the granulated particle 100 for cold storage particles is, for example, equal to or higher than 1 and equal to or lower than 5. The aspect ratio of the granulated particle 100 for cold storage particles is a ratio of the major axis to the minor axis of the granulated particle 100 for cold storage particles.

A shape of the granulated particle 100 for cold storage particles is, for example, a spherical shape, a spindle shape, or an irregular shape.

In the present specification, the particle size of the granulated particle 100 for cold storage particles is an equivalent circle diameter. The equivalent circle diameter is a diameter of a true circle corresponding to an area of a figure observed in an image such as an optical microscope image or a scanning electron microscope (SEM) image. The particle size of the granulated particle 100 for cold storage particles can be obtained, for example, by image analysis of the optical microscope image or the SEM image.

The granulated particle 100 for cold storage particles includes the first region 10a and the second region 10b.

The first region 10a is positioned inside the granulated particle 100 for cold storage particles. The first region 10a has a first void fraction. The first void fraction is, for example, equal to or higher than 10% and equal to or lower than 50%.

The second region 10b is closer to an outer edge of the particle than the first region 10a. The second region 10b is positioned at an outer circumferential portion of the granulated particle 100 for cold storage particles. The second region 10b surrounds, for example, the first region 10a.

The second region 10b has a second void fraction. The second void fraction is smaller than the first void fraction. The second void fraction is, for example, equal to or higher than 0.01% and equal to or lower than 80% of the first void fraction. In other words, a percentage of the second void fraction to the first void fraction is equal to or higher than 0.01% and equal to or lower than 80%.

The second void fraction is, for example, equal to or higher than 0% and equal to or lower than 10%.

The void fraction is an area percentage of the voids 11 in a cross section of the granulated particle 100 for cold storage particles.

The void fraction is calculated, for example, from a cross section of the granulated particle 100 for cold storage particles solidified with a resin, in an image obtained using a scanning electron microscope (SEM). For example, in an image obtained at a magnification of 5,000 times, an area percentage of the voids 11 in a region of 20 μm×20 μm is calculated. For example, the voids 11 and the other portions are automatically determined using image processing software, and the area percentage of the voids 11 is calculated.

Regarding the cross section, a sample obtained by impregnating the particle in a resin and then polishing the particle by ion milling to expose the cross section was used. At this time, when polishing is performed using a polishing paper, a portion of the particle having weak strength falls off, and thus there is a possibility that it may not be possible to accurately evaluate the voids. Therefore, it is desirable to perform polishing by ion milling that is unlikely to cause a portion to fall off.

Regarding the granulated particle for cold storage particles which is an evaluation target, particles having an equivalent circle diameter of a particle cross section within ±10% from a median of a particle size distribution of the particles were selected, and voids were observed. This is because particles in which the equivalent circle diameter of the cross section is out of the range of ±10% from the median of the particle size distribution means that the cross section is away from a particle central portion, and there is a possibility that it may not be possible to accurately evaluate a percentage of voids present in the particle.

In FIG. 1, a cross-sectional shape of the void 11 is illustrated by a circle, but the cross-sectional shape of the void 11 may not necessarily be a circle. The cross-sectional shape of the void 11 is, for example, an ellipse or an irregular shape, and the shape is not limited.

A distance of the second region 10b from an outer edge toward an inner side of the granulated particle 100 for cold storage particles is, for example, preferably shorter than 20%, more preferably shorter than 18%, and still more preferably shorter than 15% of the particle size of the granulated particle 100 for cold storage particles. The distance of the first region 10a from the outer edge toward the inner side of the granulated particle 100 for cold storage particles is, for example, equal to or longer than 15% of the particle size of the granulated particle 100 for cold storage particles. The distance from the outer edge toward the inner side of the granulated particle 100 for cold storage particles is a straight line from one point at the outer edge to another point at the outer edge. This straight line matches a straight line on which the maximum diameter of the granulated particle 100 for cold storage particles is obtained.

Next, an example of a method for manufacturing the granulated particle for cold storage particles according to the first embodiment will be described.

First, raw material powders are prepared. As the raw material powders, for example, an oxide or an oxysulfide is used. A type and percentage of the oxide or the oxysulfide are adjusted in accordance with a target composition of the cold storage particle.

The rare-earth oxysulfide contained in the raw material powders contains at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). In addition, the rare-earth oxide contained in the raw material powders contains at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

Next, the raw material powders are added to and mixed in an alginate aqueous solution to prepare a slurry. For example, a ball mill is used for mixing the raw material powders and the alginate aqueous solution. The alginate aqueous solution is, for example, a sodium alginate aqueous solution, an ammonium alginate aqueous solution, or a potassium alginate aqueous solution.

Next, defoaming of the prepared slurry is performed. The defoaming of the slurry is performed by leaving the slurry in vacuum. The defoaming of the slurry reduces gas in the slurry.

The defoamed slurry is added in drops into the gelling solution to cause the slurry to gel. For example, a dropper, a burette, a pipette, a syringe, a dispenser, or an inkjet is used to add the slurry in drops into the gelling solution. By causing the slurry to gel, spherical particles containing the raw material powders are formed in the gelling solution.

Examples of the gelling solution include a calcium lactate aqueous solution, a calcium chloride aqueous solution, a manganese (II) chloride aqueous solution, a magnesium sulfate aqueous solution, a beryllium sulfate aqueous solution, a strontium nitrate aqueous solution, an aluminum chloride aqueous solution, an aluminum nitrate aqueous solution, an aluminum lactate aqueous solution, an iron (II) chloride aqueous solution, an iron (III) chloride aqueous solution, a copper (II) chloride aqueous solution, a nickel (II) chloride aqueous solution, and a cobalt (II) chloride aqueous solution.

After particles are formed by gelation, the particles are washed with pure water and dried.

The granulated particle 100 for cold storage particles of the first embodiment can be manufactured by the above-described manufacturing method.

By adjusting a defoaming time, a gelling solution concentration, and a gelling time of the slurry, the granulated particle 100 for cold storage particles having a desired void fraction can be manufactured. In particular, it is conceivable that the defoaming of the slurry enables the first region 10a and the second region 10b having respective different void fractions to be formed in the granulated particle 100 for cold storage particles to be manufactured.

The ceramic magnetic cold storage particles are manufactured, for example, by sintering granulated particles obtained by gelling of raw material powders. When the strength of the gelled granulated particles is low, for example, a problem arises in that the granulated particles are broken during conveyance before sintering. Hence, realization of granulated particles for cold storage particles having high mechanical strength is anticipated.

As illustrated in FIG. 1, the granulated particle 100 for cold storage particles of the first embodiment includes the second region 10b that is closer to the outer edge of the particle than the first region 10a and has a second void fraction lower than the first void fraction. Since the void fraction of the second region 10b is smaller than that of the first region 10a, the mechanical strength is higher than that of the first region 10a.

Hence, the mechanical strength of the granulated particle 100 for cold storage particles increases. Thus, it is possible to suppress breakage of the granulated particle 100 for cold storage particles before sintering.

For example, in a case where cold storage particles containing rare-earth oxysulfide are manufactured, the granulated particle for cold storage particles containing rare-earth oxide as the raw material powder is subjected to a heat treatment for sulfurization of the raw material powder. By the heat treatment, the rare-earth oxide is sulfurized to form the rare-earth oxysulfide. After the heat treatment for sulfurization of the raw material powder is performed, the granulated particle for cold storage particles is sintered to manufacture cold storage particles containing rare-earth oxysulfide.

In the granulated particle 100 for cold storage particles of the first embodiment, the first void fraction of the first region 10a is higher than the second void fraction of the second region 10b. Therefore, it is easy for sulfidizing gas to permeate the first region 10a during the heat treatment for sulfurization of the raw material powders. Hence, the sulfurization of the raw material powders is promoted. Thus, sufficient sulfurization of the raw material powders in the granulated particle 100 for cold storage particles can be realized. Since sufficient sulfurization can be realized, a presence percentage of oxysulfide contributing to specific heat increases, and specific heat of the sintered particles increases.

According to the granulated particle 100 for cold storage particles of the first embodiment, both the high mechanical strength and the sufficient sulfurization of the raw material powders can be achieved.

From the viewpoint of enhancing the mechanical strength of the granulated particle 100 for cold storage particles, the second void fraction is preferably equal to or lower than 80% of the first void fraction, more preferably equal to or lower than 20%, and still more preferably equal to or lower than 10%.

From the viewpoint of improving a degree of progress of sulfurization of the granulated particle 100 for cold storage particles, the second void fraction is preferably equal to or higher than 0.01% of the first void fraction, more preferably equal to or higher than 0.1%, and still more preferably equal to or higher than 1%.

Therefore, in the granulated particle 100 for cold storage particles, the second void fraction is preferably equal to or higher than 0.01% and equal to or lower than 80% of the first void fraction, more preferably equal to or higher than 0.1% and equal to or lower than 20%, and still more preferably equal to or higher than 1% and 10%. Within such a range, both the mechanical strength and the degree of progress of sulfurization of the granulated particle 100 for cold storage particles can be improved.

From the viewpoint of enhancing the mechanical strength of the granulated particle 100 for cold storage particles, the second void fraction is preferably lower than 10%, and more preferably equal to or lower than 5%. From the viewpoint of enhancing the mechanical strength of the granulated particle 100 for cold storage particles, the first void fraction is preferably equal to or lower than 50%.

From the viewpoint of improving the degree of progress of sulfurization of the granulated particle 100 for cold storage particles, the first void fraction is preferably equal to or higher than 10%, more preferably equal to or higher than 20%, and still more preferably equal to or higher than 30%. From the viewpoint of improving the degree of progress of sulfurization of the granulated particle 100 for cold storage particles, the second void fraction is preferably equal to or higher than 0.1%, and more preferably equal to or higher than 1%.

From the viewpoint of lowering a temperature of the heat treatment for sulfurization or sintering, or from the viewpoint of shortening a time of the heat treatment for the sulfurization or the sintering, a relative density of the granulated particle 100 for cold storage particles is preferably equal to or lower than 50%, and more preferably equal to or lower than 40%.

When the relative density of the granulated particle 100 for cold storage particles is lower than 10%, for example, the percentage of voids in the granulated particle 100 for cold storage particles increases, and the mechanical strength of the granulated particle 100 for cold storage particles decreases.

In addition, when the relative density of the granulated particles for the cold storage particles is lower than 10%, for example, the relative density of the manufactured cold storage particles decreases, and the specific heat of the cold storage particles decreases. This is considered to be because the number of contact points between the raw material powders decreases and the sinterability of the cold storage particles decreases.

Hence, the granulated particle 100 for cold storage particles preferably has the relative density equal to or higher than 10%.

### Modification Example

A granulated particle for cold storage particles of a modification example of the first embodiment differs from the granulated particle for cold storage particles of the first embodiment in that the second region is provided only at a part of the outer circumferential portion of the particle.

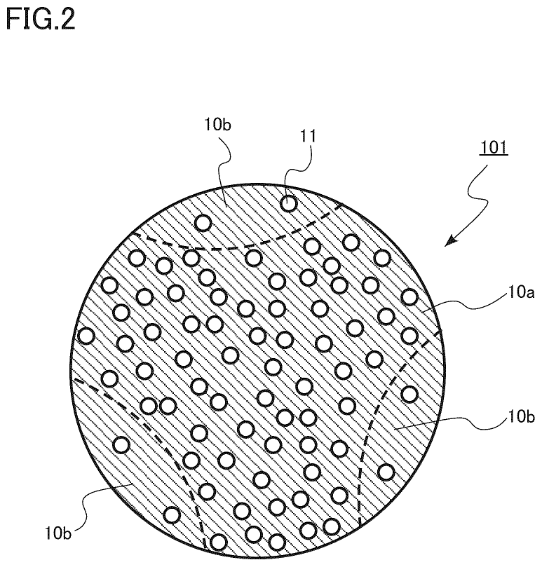

FIG. 2 is a schematic cross-sectional view of the granulated particle for cold storage particles according to the modification example of the first embodiment.

A granulated particle 101 for cold storage particles of the modification example of the first embodiment has a second region 10b that is provided only at a part of an outer circumference of the particle. The second region 10b does not surround a first region 10a.

According to the granulated particle 101 for cold storage particles of the modification example of the first embodiment, both the high mechanical strength and the sufficient sulfurization of the raw material powders can be achieved, similarly to the granulated particle 100 for cold storage particles of the first embodiment.

As described above, according to the first embodiment and the modification example, it is possible to provide the granulated particle for cold storage particles having the high mechanical strength. In addition, according to the first embodiment and the modification example, it is possible to provide the granulated particle for cold storage particles in which sufficient sulfurization of the raw material powders can be realized.

### Second Embodiment

A granulated particle for cold storage particles of a second embodiment differs from the granulated particle for cold storage particles of the first embodiment in that a third region that is farther away from an outer edge of the particle than the first region and has a third void fraction lower than the first void fraction is further provided. Hereinafter, the repeated descriptions of the details described in the first embodiment may be partially omitted.

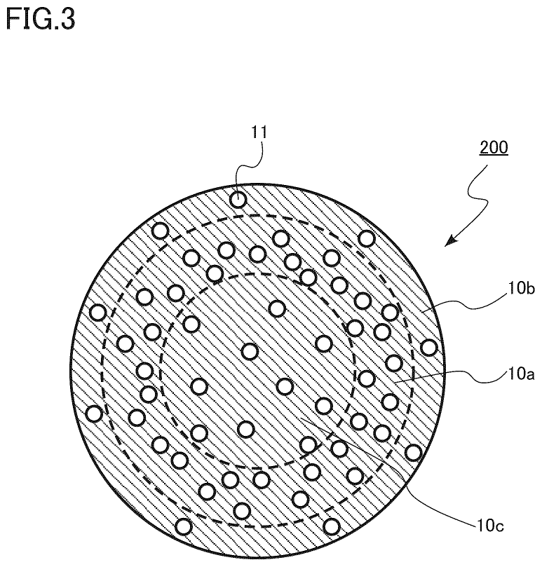

FIG. 3 is a schematic cross-sectional view of the granulated particle for cold storage particles according to the second embodiment.

As illustrated in FIG. 3, a granulated particle 200 for cold storage particles of the second embodiment includes a first region 10a, a second region 10b, and a third region 10c. In addition, the granulated particle 200 for cold storage particles includes voids 11.

The first region 10a has a first void fraction. The first void fraction is, for example, equal to or higher than 10% and equal to or lower than 50%.

The second region 10b is closer to an outer edge of the particle than the first region 10a. The second region 10b is positioned at an outer circumferential portion of the granulated particle 200 for cold storage particles. The second region 10b surrounds, for example, the first region 10a.

The second region 10b has a second void fraction. The second void fraction is smaller than the first void fraction. The second void fraction is, for example, equal to or higher than 0.01% and equal to or lower than 80% of the first void fraction. In other words, a percentage of the second void fraction to the first void fraction is equal to or higher than 0.01% and equal to or lower than 80%.

The second void fraction is, for example, equal to or higher than 0% and equal to or lower than 10%.

The third region 10c is farther away from the outer edge of the particle than the first region 10a. The third region 10c is positioned at a central portion of the granulated particle 200 for cold storage particles. The first region 10a surrounds, for example, the third region 10c.

The third region 10c has a third void fraction. The third void fraction is smaller than the first void fraction. The third void fraction is, for example, equal to or higher than 0.01% and equal to or lower than 80% of the first void fraction. In other words, a percentage of the third void fraction to the first void fraction is equal to or higher than 0.01% and equal to or lower than 80%.

The third void fraction is, for example, equal to or higher than 0% and lower than 10%.

A distance of the second region 10b from an outer edge toward an inner side of the granulated particle 200 for cold storage particles is, for example, preferably shorter than 20%, more preferably shorter than 18%, and still more preferably shorter than 15% of the particle size of the granulated particle 200 for cold storage particles. In addition, the distance of the first region 10a from the outer edge toward the inner side of the granulated particle 200 for cold storage particles is, for example, equal to or longer than 15% and shorter than 40% of the particle size of the granulated particle 200 for cold storage particles. In addition, the distance of the third region 10c from the outer edge toward the inner side of the granulated particle 200 for cold storage particles is, for example, equal to or longer than 40% and equal to or shorter than 50% of the particle size of the granulated particle 200 for cold storage particles.

The granulated particle 200 for cold storage particles of the second embodiment can be manufactured, for example, by adjusting conditions for defoaming the slurry in the method for manufacturing the granulated particle 100 for cold storage particles of the first embodiment.

According to the granulated particle 200 for cold storage particles of the second embodiment, both the high mechanical strength and the sufficient sulfurization of the raw material powders can be achieved, similarly to the granulated particle 100 for cold storage particles of the first embodiment. In addition, the granulated particle 200 for cold storage particles of the second embodiment includes the third region 10c having the void fraction smaller than that of the first region 10a at the central portion, so that higher mechanical strength can be realized.

As described above, according to the second embodiment, it is possible to provide the granulated particle for cold storage particles having the high mechanical strength. In addition, according to the second embodiment, it is possible to provide the granulated particle for cold storage particles in which sufficient sulfurization of the raw material powders can be realized.

### Third Embodiment

Cold storage particles of a third embodiment are obtained by sintering the granulated particle 100 for cold storage particles of the first embodiment.

The cold storage particles of the third embodiment have a particle size of, for example, equal to or larger than 50 μm and equal to or smaller than 5 mm. An aspect ratio of the cold storage particles is, for example, equal to or higher than 1 and equal to or lower than 5. The aspect ratio of the cold storage particles is a ratio of the major axis to the minor axis of the cold storage particles. A shape of the cold storage particles is, for example, spherical.

The cold storage particles of the third embodiment have, for example, a relative density equal to or higher than 90%.

The cold storage particles of the third embodiment are cold storage particles manufactured from the granulated particle 100 for cold storage particles of the first embodiment. The cold storage particles of the third embodiment contain, for example, rare-earth oxysulfide or rare-earth oxide.

The rare-earth oxysulfide included in the cold storage particles contains at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). In addition, the rare-earth oxide included in the cold storage particles contains at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

A maximum value of volumetric specific heat of the cold storage particles of the third embodiment in a temperature range of 2 K or higher to 10 K or lower is equal to or larger than 0.5 J/(cm³·K), for example.

The cold storage particles of the third embodiment contain, for example, rare-earth oxysulfide represented by a general formula of R_{2±0.1}O₂S_{1±0.1} (in the formula, R represents at least one rare-earth element selected from the group consisting of Y, La, Ce, Pr, Nd, Sm, Eu, Gd, Tb, Dy, Ho, Er, Tm, Yb, and Lu).

In the rare-earth oxysulfide represented by the above-described general formula, a maximum value of the volumetric specific heat and a temperature indicating the maximum value of the volumetric specific heat are different depending on the selected rare-earth elements. Therefore, the specific heat characteristics of rare-earth oxysulfide can be adjusted by appropriately adjusting a percentage of the rare-earth elements. The rare-earth elements are, for example, at least one element selected from the group consisting of Gd, Tb, Dy, Ho, and Er. The rare-earth elements may include, for example, two or more kinds of rare-earth elements.

The cold storage particles of the third embodiment contain, for example, rare-earth oxide represented by a general formula of R_{1±0.1}M_{1±0.1}O_{3±0.1} (in the formula, R represents at least one element selected from the group consisting of Y, La, Ce, Pr, Nd, Pm, Sm, Eu, Gd, Tb, Dy, Ho, Er, Tm, Yb, and Lu, and M represents at least one element selected from the group consisting of Al, Cr, Mn, and Fe).

In the rare-earth oxide represented by the above-described general formula, a maximum value of the volumetric specific heat and a temperature indicating the maximum value of the volumetric specific heat are different depending on the selected rare-earth elements. Therefore, the specific heat characteristics of rare-earth oxide can be adjusted by appropriately adjusting a percentage of the rare-earth elements. The rare-earth elements are, for example, at least one element selected from the group consisting of Gd, Tb, Dy, Ho, and Er. The rare-earth elements may include, for example, two or more kinds of rare-earth elements.

A maximum value of the volumetric specific heat of the cold storage particles of the third embodiment in a temperature range of 2 K or higher to 10 K or lower is equal to or larger than 0.5 J/(cm³·K), for example. Hence, the cold storage particles of the third embodiment have high volumetric specific heat. Since the cold storage particles of the third embodiment have the high volumetric specific heat, a regenerator filled with the cold storage particles of the third embodiment has high cold storage performance, and a refrigerator exhibits high refrigerating capacity.

The granulated particle 100 of cold storage particles of the first embodiment is subjected to the heat treatment for sintering, and thereby the cold storage particles of the third embodiment are manufactured.

For example, in a case where oxides are used as the raw material powders of the granulated particle 100 for cold storage particles to manufacture cold storage particles containing oxysulfide, the granulated particle 100 for cold storage particles is sulfurized. In this case, the heat treatment is performed in a sulfidizing atmosphere. In the sulfidizing atmosphere, for example, a gas containing sulfur atoms having a negative oxidation number, such as hydrogen sulfide (H₂S), carbon sulfide (CS₂), or methanethiol (CH₃SH) is contained. A temperature of the heat treatment for sulfurization is, for example, equal to or higher than 400° C. and equal to or lower than 600° C. In addition, a time for the heat treatment of sulfurization is, for example, equal to or longer than one hour and equal to or shorter than five hours.

The heat treatment for sintering the obtained oxysulfide is performed, for example, in an inert gas atmosphere. The heat treatment temperature is, for example, equal to or higher than 1,100° C. and equal to or lower than 2,000° C. The heat treatment time is, for example, equal to or longer than one hour and equal to or shorter than 48 hours.

The cold storage particles of the third embodiment are manufactured by sintering the granulated particle 100 for cold storage particles of the first embodiment. Therefore, for example, breakage of the granulated particle 100 for cold storage particles is suppressed, and a high manufacturing yield of the cold storage particles can be realized. In addition, for example, sufficient sulfurization of the raw material powders can be realized, and a high manufacturing yield of the cold storage particles can be realized. Hence, for example, manufacturing costs of the cold storage particles can be reduced.

As described above, according to the third embodiment, it is possible to provide the cold storage particles that enable the high manufacturing yield to be realized and enable the manufacturing costs to be reduced.

### Fourth Embodiment

A regenerator of a fourth embodiment is a regenerator filled with a plurality of cold storage particles of the third embodiment. In the regenerator of the fourth embodiment, for example, when the perimeter of the projection image of the plurality of filled cold storage particles of the third embodiment is denoted by L and the actual area of the projection image is denoted by A, a percentage of the cold storage particles having the circularity R equal to or lower than 0.5 which is represented by 4 nA/L² is equal to or lower than 5%.

The circularity R can be obtained by performing image processing on the shapes of the plurality of cold storage particles by using an optical microscope. The cold storage particles having the circularity R equal to or lower than 0.5 have, for example, a shape having unevenness on a surface thereof. When the regenerator is filled with a plurality of cold storage particles of which the cold storage particles having such a shape are more than 5%, a void fraction in the regenerator becomes non-uniform, or fillability becomes unstable. Therefore, when a working medium flows in, the cold storage performance deteriorates, or the cold storage particles are moved or broken to form fine particles due to stress applied to the cold storage particles at the time of filling the cold storage particles or at the time of operating the refrigerator, and the fine particles clog the voids. Consequently, refrigeration performance or long-term reliability of the refrigerator is degenerated. The cold storage particles having the circularity R equal to or lower than 0.5 is preferably equal to or lower than 2%, and more preferably 0%.

### Fifth Embodiment

A refrigerator of a fifth embodiment is a refrigerator including the regenerator of the fourth embodiment filled with the plurality of the cold storage particles of the third embodiment. Hereinafter, the repeated descriptions of the details described in the third and fourth embodiments are partially omitted.

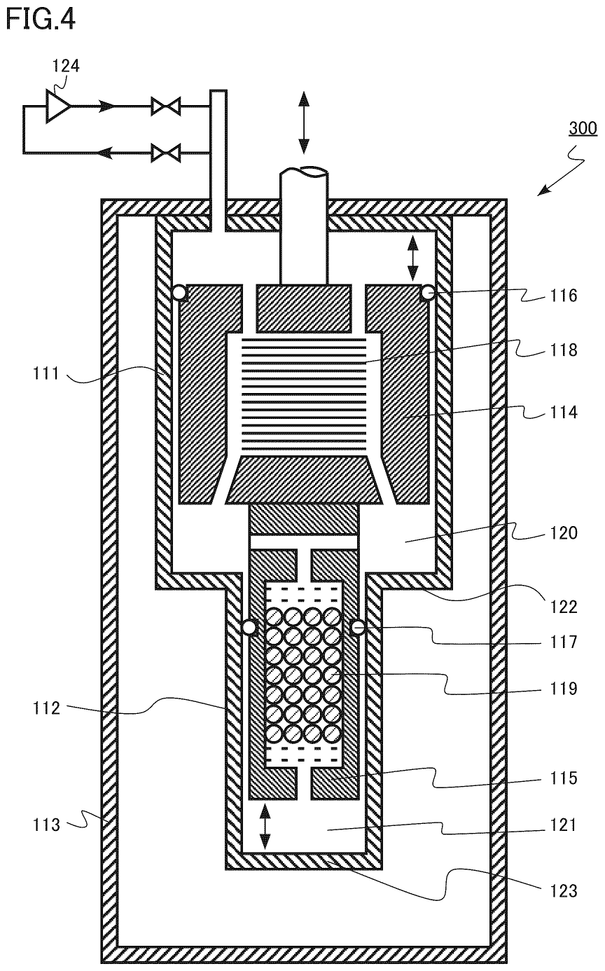

FIG. 4 is a schematic cross-sectional view illustrating a configuration of a main part of the refrigerator of the fifth embodiment. FIG. 4 is a schematic cross-sectional view illustrating a configuration of a main part of a GM refrigerator which is an example of the refrigerator of the fifth embodiment. The GM refrigerator which is an example of the refrigerator of the fifth embodiment includes the regenerator of the fourth embodiment filled with the plurality of cold storage particles of the third embodiment.

The refrigerator of the fifth embodiment is a two-stage regenerative cryogenic refrigerator 300 used for cooling a superconducting machine or the like. The refrigerator may be, for example, a Stirling refrigerator or a pulse tube refrigerator.

The regenerative cryogenic refrigerator 300 (refrigerator) includes a first cylinder 111, a second cylinder 112, a vacuum container 113, a first regenerator 114, a second regenerator 115 (regenerator), a first seal ring 116, a second seal ring 117, a first cold storage material 118, a second cold storage material 119 (cold storage particles), a first expansion chamber 120, a second expansion chamber 121, a first cooling stage 122, a second cooling stage 123, and a compressor 124.

The regenerative cryogenic refrigerator 300 includes the vacuum container 113 in which a first cylinder 111 having a large diameter and a second cylinder 112 having a small diameter which is coaxially connected to the first cylinder 111 are provided. The first regenerator 114 is disposed in the first cylinder 111 to freely perform reciprocating motion. In the second cylinder 112, the second regenerator 115 which is an example of the regenerator of the fourth embodiment is disposed to freely perform reciprocating motion.

The first seal ring 116 is disposed between the first cylinder 111 and the first regenerator 114. The second seal ring 117 is disposed between the second cylinder 112 and the second regenerator 115.

The first regenerator 114 is filled with a first cold storage material 118 such as Cu mesh. The second regenerator 115 is filled with a plurality of the cold storage particles of the third embodiment as the second cold storage material 119.

The second regenerator 115 may be divided by a metal mesh material and may include a plurality of cold storage material filling layers. In a case where the second regenerator 115 is divided into a plurality of filling layers, at least one filling layer is filled with a cold storage particle group including a plurality of cold storage particles of the third embodiment. Then, for example, a combination with at least one cold storage particle group selected from a lead cold storage particle group, a bismuth cold storage particle group, a tin cold storage particle group, a holmium copper cold storage particle group, an erbium nickel cold storage particle group, an erbium cobalt cold storage particle group, and a gadolinium aluminum oxide cold storage particle group is used.

In the combination of the cold storage materials, the one having a higher peak temperature of specific heat is defined as a first cold storage particle group, the one having a lower peak temperature of specific heat is defined as a second cold storage particle group, and the combination is performed so that the peak temperature of specific heat is sequentially lowered.

In a case of a two-layer type, a combination or the like is performed in which the holmium copper cold storage particle group is used as the first cold storage particle group, and the cold storage particle group of the third embodiment is used as the second cold storage particle group. In addition, in a case of a three-layer type, a combination or the like is performed in which at least one kind of cold storage particle group selected from a lead cold storage particle group, a bismuth cold storage particle group, and a tin cold storage particle group is used as the first cold storage particle group, a holmium copper cold storage particle group is used as the second cold storage particle group, and the cold storage particle group of the third embodiment is used as the third cold storage particle group.

Holmium copper cold storage particles are preferably, for example, HoCu₂ or HoCu. Erbium-nickel cold storage particles are preferably, for example, ErNi or Er₃Ni.

The first regenerator 114 and the second regenerator 115 each have a passage of a working medium which is provided in a gap or the like between the first cold storage material 118 and the second cold storage material 119. The working medium is helium gas.

The first expansion chamber 120 is provided between the first regenerator 114 and the second regenerator 115. In addition, the second expansion chamber 121 is provided between the second regenerator 115 and a distal end wall of the second cylinder 112. The first cooling stage 122 is provided at the bottom of the first expansion chamber 120. In addition, the second cooling stage 123 having a temperature lower than that of the first cooling stage 122 is formed at the bottom of the second expansion chamber 121.

A high-pressure working medium is supplied from the compressor 124 to the above-described two-stage regenerative cryogenic refrigerator 300. The supplied working medium passes through the first cold storage material 118, with which the first regenerator 114 is filled, and reaches the first expansion chamber 120. Then, the working medium passes through the second cold storage material 119, with which the second regenerator 115 is filled, and reaches the second expansion chamber 121.

At this time, the working medium is cooled by supplying thermal energy to the first cold storage material 118 and the second cold storage material 119. The working medium passing through the first cold storage material 118 and the second cold storage material 119 expands in the first expansion chamber 120 and the second expansion chamber 121, and cooling is performed. Then, the first cooling stage 122 and the second cooling stage 123 are cooled.

The expanded working medium flows in an opposite direction through the first cold storage material 118 and the second cold storage material 119. The working medium receives thermal energy from the first cold storage material 118 and the second cold storage material 119 and then is discharged. The regenerative cryogenic refrigerator 300 is configured such that thermal efficiency of the working medium cycle is enhanced as a recuperative effect is improved in such a process, and a lower temperature is realized.

In the regenerator included in the regenerative cryogenic refrigerator 300 of the fifth embodiment, the second regenerator 115 is filled with the plurality of cold storage particles of the third embodiment as the second cold storage material 119. At least a part of the second cold storage material 119 is the cold storage particles of the third embodiment.

Regarding the plurality of cold storage particles of the third embodiment, when the perimeter of each projection image of the cold storage particles is denoted by L and the actual area of the projection image is denoted by A, the cold storage particles having the circularity R equal to or lower than 0.5 which is represented by 4 nA/L² are preferably equal to or more than 5%.

In order to improve the refrigerating capacity of the refrigerator, it is desirable to improve specific heat per unit volume of the cold storage material and improve thermal conductivity and a heat transfer coefficient. The regenerative cryogenic refrigerator 300 of the fifth embodiment includes a cold storage material or cold storage particles which maintain volumetric specific heat and are improved in the thermal conductivity and the thermal conductivity. The regenerative cryogenic refrigerator 300 of the fifth embodiment includes a cold storage material or cold storage particles enabling the manufacturing costs to be reduced.

For example, by using the regenerative cryogenic refrigerator 300 of the fifth embodiment in a magnetic levitation train, the long-term reliability of the magnetic levitation train can be improved.

As described above, according to the fifth embodiment, it is possible to realize the refrigerator having good characteristics by using the cold storage particles having good characteristics.

### Sixth Embodiment

A cryopump of a sixth embodiment includes the refrigerator of the fifth embodiment. Hereinafter, the repeated descriptions of the details described in the fifth embodiment are partially omitted.

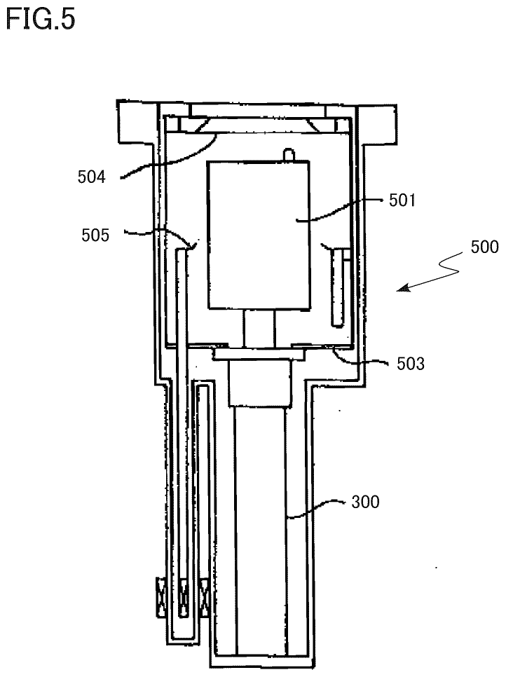

FIG. 5 is a cross-sectional view illustrating a schematic configuration of the cryopump of the sixth embodiment. The cryopump of the sixth embodiment is a cryopump 500 including the regenerative cryogenic refrigerator 300 of the fifth embodiment.

The cryopump 500 includes a cryopanel 501 that condenses or adsorbs gas molecules, the regenerative cryogenic refrigerator 300 that cools the cryopanel 501 to a predetermined cryogenic temperature, a shield 503 provided between the cryopanel 501 and the regenerative cryogenic refrigerator 300, a baffle 504 provided at an inlet, and a ring 505 that changes an exhaust velocity of argon, nitrogen, hydrogen, or the like.

According to the sixth embodiment, it is possible to realize the cryopump having good characteristics by using the refrigerator having good characteristics. In addition, by using the cryopump according to the sixth embodiment in a semiconductor manufacturing apparatus or the like, the long-term reliability of the semiconductor manufacturing apparatus can be enhanced, and the number of times of maintenance of the semiconductor manufacturing apparatus can be reduced. As a result, this contributes to improvement in quality of semiconductors to be manufactured and reduction in manufacturing cost.

### Seventh Embodiment

A superconducting magnet of a seventh embodiment includes the refrigerator of the fifth embodiment. Hereinafter, the repeated descriptions of the details described in the fifth embodiment are partially omitted.

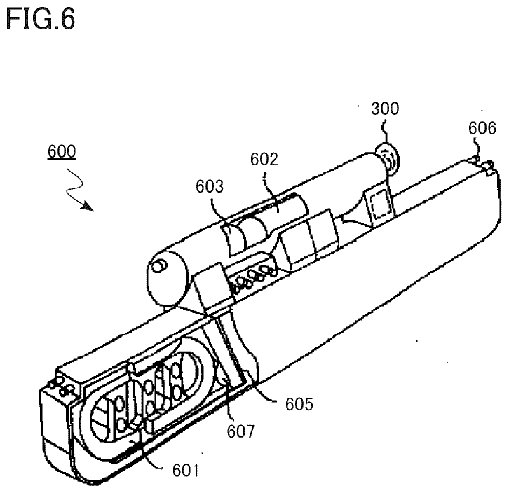

FIG. 6 is a perspective view illustrating a schematic configuration of the superconducting magnet of the seventh embodiment. The superconducting magnet of the seventh embodiment is a superconducting magnet 600 for a magnetic levitation train, the superconducting magnet including the regenerative cryogenic refrigerator 300 of the fifth embodiment.

The superconducting magnet 600 for a magnetic levitation train includes a superconducting coil 601, a liquid helium tank 602 for cooling the superconducting coil 601, a liquid nitrogen tank 603 for preventing liquid helium from volatilizing, a multi-layer insulation material 605, a power lead 606, a permanent current switch 607, and the regenerative cryogenic refrigerator 300.

According to the seventh embodiment, it is possible to realize the superconducting magnet having good characteristics by using the refrigerator having good characteristics.

### Eighth Embodiment

A nuclear magnetic resonance imaging apparatus of an eighth embodiment includes the refrigerator of the fifth embodiment. Hereinafter, the repeated descriptions of the details described in the fifth embodiment are partially omitted.

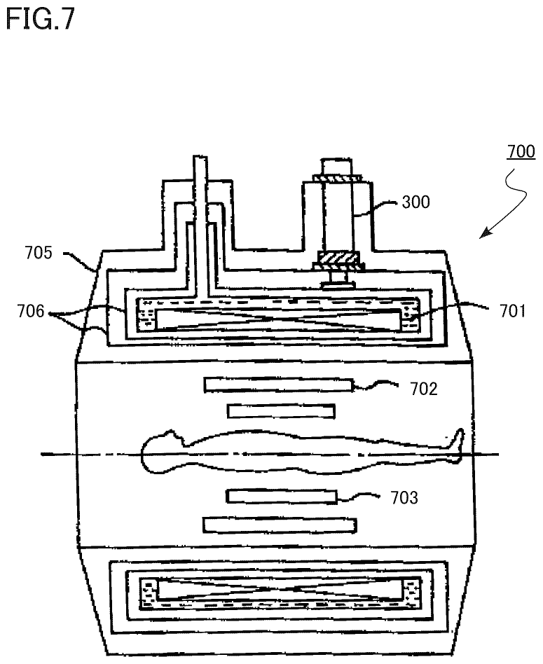

FIG. 7 is a cross-sectional view illustrating a schematic configuration of the nuclear magnetic resonance imaging apparatus of the eighth embodiment. The nuclear magnetic resonance imaging (MRI) apparatus of the eighth embodiment is a nuclear magnetic resonance imaging apparatus 700 including the regenerative cryogenic refrigerator 300 of the fifth embodiment.

The nuclear magnetic resonance imaging apparatus 700 includes a superconducting static magnetic field coil 701 that applies a spatially uniform and temporally stable static magnetic field to a human body, a correction coil (not illustrated) that corrects nonuniformity of a generated magnetic field, a gradient magnetic field coil 702 that gives a magnetic field gradient to a measurement region, a radio wave transmission/reception probe 703, a cryostat 705, and a radiation adiabatic shield 706. The regenerative cryogenic refrigerator 300 is used for cooling the superconducting static magnetic field coil 701.

According to the eighth embodiment, it is possible to realize the nuclear magnetic resonance imaging apparatus having good characteristics by using the refrigerator having good characteristics.

### Ninth Embodiment

A nuclear magnetic resonance apparatus of a ninth embodiment includes the refrigerator of the fifth embodiment. Hereinafter, the repeated descriptions of the details described in the fifth embodiment are partially omitted.

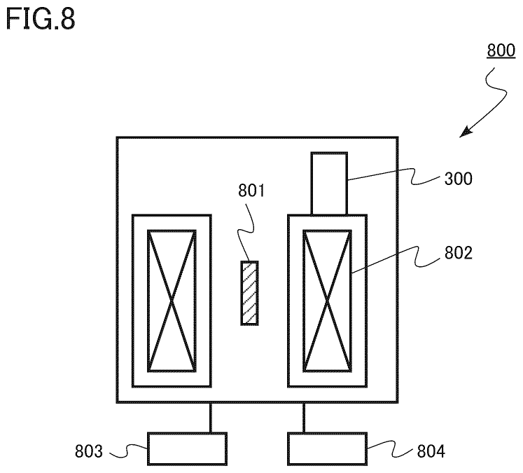

FIG. 8 is a cross-sectional view illustrating a schematic configuration of the nuclear magnetic resonance apparatus of the ninth embodiment. The nuclear magnetic resonance (NMR) apparatus of the ninth embodiment is a nuclear magnetic resonance apparatus 800 including the regenerative cryogenic refrigerator 300 of the fifth embodiment.

The nuclear magnetic resonance apparatus 800 includes a superconducting static magnetic field coil 802 that applies a magnetic field to a sample such as an organic substance placed in a sample tube 801, a high frequency oscillator 803 that applies a radio wave to the sample tube 801 in a magnetic field, and an amplifier 804 that amplifies an induced current generated in a coil (not illustrated) around the sample tube 801. In addition, the nuclear magnetic resonance apparatus 800 includes the regenerative cryogenic refrigerator 300 that cools the superconducting static magnetic field coil 802.

According to the ninth embodiment, it is possible to realize the nuclear magnetic resonance apparatus having good characteristics by using the refrigerator having good characteristics.

### Tenth Embodiment

A magnetic field application-type single crystal pulling-out apparatus of a tenth embodiment includes the refrigerator of the fifth embodiment. Hereinafter, the repeated descriptions of the details described in the fifth embodiment are partially omitted.

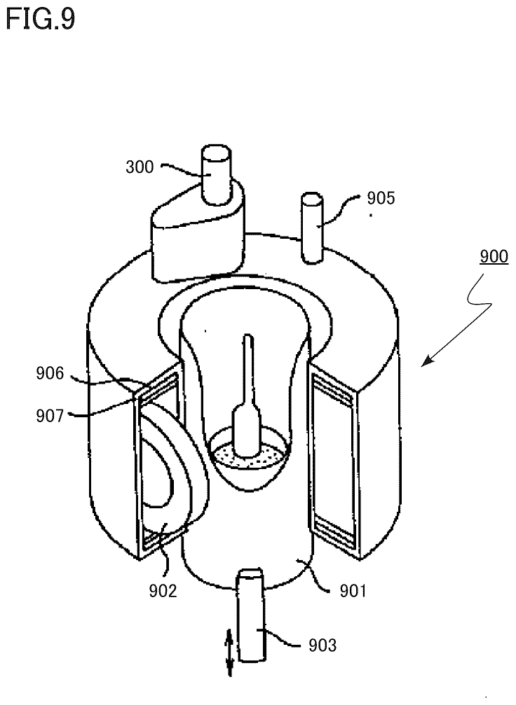

FIG. 9 is a perspective view illustrating a schematic configuration of the magnetic field application-type single crystal pulling-out apparatus of the tenth embodiment. The magnetic field application-type single crystal pulling-out apparatus of the tenth embodiment is a magnetic field application-type single crystal pulling-out apparatus 900 including the regenerative cryogenic refrigerator 300 of the fifth embodiment.

The magnetic field application-type single crystal pulling-out apparatus 900 includes a single crystal pulling-out unit 901 having a raw material melting crucible, a heater, a single crystal pulling-out mechanism, and the like, a superconducting coil 902 that applies a static magnetic field to raw material melt, a lifting-lowering mechanism 903 of the single crystal pulling-out unit 901, a current lead 905, a heat shield plate 906, and a helium container 907. The regenerative cryogenic refrigerator 300 is used for cooling the superconducting coil 902.

According to the tenth embodiment, it is possible to realize the magnetic field application-type single crystal pulling-out apparatus having good characteristics by using the refrigerator having good characteristics.

### Eleventh Embodiment

A helium recondensing apparatus of an eleventh embodiment includes the refrigerator of the fifth embodiment. Hereinafter, the repeated descriptions of the details described in the fifth embodiment are partially omitted.

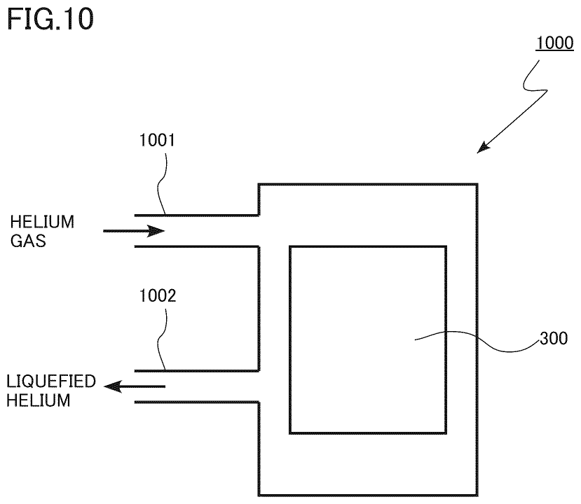

FIG. 10 is a schematic view illustrating a schematic configuration of the helium recondensing apparatus of the eleventh embodiment. The helium recondensing apparatus of the eleventh embodiment is a helium recondensing apparatus 1000 including the regenerative cryogenic refrigerator 300 of the fifth embodiment.

The helium recondensing apparatus 1000 includes the regenerative cryogenic refrigerator 300, an evaporation pipe 1001, and a liquefaction pipe 1002.

The helium recondensing apparatus 1000 can recondense helium gas evaporating from a liquid helium apparatus into liquid helium. The liquid helium apparatus is, for example, the superconducting magnet, the nuclear magnetic resonance (NMR) apparatus, the nuclear magnetic resonance imaging (MRI) apparatus, a physical property measurement system (PPMS), or a magnetic property measurement system.

Helium gas is introduced from the liquid helium apparatus (not illustrated) into the helium recondensing apparatus 1000 through the evaporation pipe 1001. The helium gas is cooled to 4 K equal to or lower than the liquefaction temperature of helium by the regenerative cryogenic refrigerator 300. The condensed and liquefied liquid helium returns to the liquid helium apparatus through the liquefaction pipe 1002.

According to the eleventh embodiment, it is possible to realize the helium recondensing apparatus having good characteristics by using the refrigerator having good characteristics.

### EXAMPLES

Hereinafter, examples, a comparative example, and evaluation results thereof regarding the granulated particle for cold storage particles of the first embodiment and the cold storage particles of the third embodiment will be described.

### Example 1

First, Gd₂O₃ powder and Al₂O₃ powder were added to a sodium alginate aqueous solution and mixed for 12 hours to prepare a slurry. The prepared slurry was left in vacuum and defoamed. A defoaming time was one hour.

The defoamed slurry was added in drops into a calcium lactate aqueous solution which is a gelling solution. A syringe was used for adding the slurry in drops. A diameter of the syringe was 510 μm, and a distance from a tip of the syringe to a liquid level of the calcium lactate aqueous solution was 100 mm. A calcium concentration of the gelling solution was 0.1 mol %.

The slurry added in drops with the syringe was left in the gelling solution for five minutes. Thereafter, a gelled particle was washed with pure water and dried. A granulated particle for cold storage particles of Example 1 was manufactured by drying the particle.

A void fraction of the manufactured granulated particle for cold storage particles was measured. A first void fraction of an inner portion of the granulated particle for cold storage particles and a second void fraction of an outer circumferential portion thereof were measured. Further, a percentage of the second void fraction to the first void fraction (second void fraction/first void fraction) was obtained.

The void fractions of the granulated particle for cold storage particles were obtained from observation of a cross section of the particle. When the cross section of the granulated particle for cold storage particles was observed, a sample obtained by impregnating the particle in a resin and then polishing the particle by ion milling to expose the cross section was used.

The cross section of the sample of which the cross section was exposed was observed using a scanning electron microscope (SEM). At this time, by comparing a secondary electron image and a backscattered electron image of the SEM, dust attached to a measurement surface was excluded such that voids were identified.

In addition, regarding the granulated particle for cold storage particles which is an evaluation target, particles having an equivalent circle diameter of a particle cross section within ±10% from a median of a particle size distribution of the particles were selected, and voids were observed.

The inner portion and the outer circumferential portion of the particle were observed by the above-described technique, and a presence percentage of the voids was quantified by image processing software ImageJ. An area percentage of a void fraction obtained by dividing the second void fraction in the outer circumferential portion by the first void fraction of the inner portion of the granulated particle for a cold storage material of Example 1 was 0.25%.

In order to evaluate a percentage of breakage of the granulated particle for a cold storage material of Example 1 during conveyance, a cylindrical container having a diameter of 15 mm and a height of 5 mm was filled with the granulated particles for cold storage particles at room temperature, and simple harmonic motion having an amplitude of 2 mm and a maximum acceleration of 100 m/s² was applied 2×10⁴ times. A weight percent of particles broken by the motion was defined as a breakage ratio.

After the evaluation of a breakage percentage, the manufactured granulated particles for cold storage particles were sulfurized. A heat treatment was performed at 500° C. for four hours in an atmosphere containing hydrogen sulfide (H₂S) to sulfurize the particles.

A main constituent element of the granulated particles for cold storage particles of Example 1 subjected to the sulfurization treatment is gadolinium oxysulfide. A secondary phase includes perovskite oxide, garnet-type oxide, or alumina.

A value obtained by dividing maximum strength derived from gadolinium oxysulfide observed in an XRD pattern in a comparative example to be described later by the maximum strength derived from a phase having the highest presence ratio in the group consisting of perovskite oxide, garnet-type oxide, and alumina is defined as a degree of sulfurization progress of the related art. When the degree of sulfurization progress in Example 1 was calculated and the value was divided by the degree of sulfurization progress of the related art, the value was 100%.

After the particles were sulfurized, a heat treatment was performed at 1,300° C. for 12 hours in a pressurized atmosphere of inert gas to sinter the particles. By sintering the particles, the cold storage particles corresponding to the third embodiment were obtained.

The relative density of the granulated particles for cold storage particles of Example 1 was 30%.

The relative density of the cold storage particles obtained by sintering the granulated particles for cold storage particles of Example 1 was equal to or higher than 90%. In addition, in the cold storage particles obtained from the granulated particle for cold storage particles of Example 1, the maximum value of the volumetric specific heat in a temperature range of 2 K or higher to 10 K or lower was equal to or larger than 0.5 J/(cm³·K).

### Examples 2 to 7

The cold storage particles of Examples 2 to 7 differ from the cold storage particles of Example 1 in a percentage of the second void fraction of the outer circumferential portion and the first void fraction of the inner portion of the granulated particles for a cold storage material. When the granulated particles for a cold storage material of Examples 2 to 7 were manufactured, a defoaming time, a gelling solution concentration, and a gelling time were changed as compared with the case of manufacturing the granulated particles for a cold storage material of Example 1. The manufactured granulated particles for a cold storage material were evaluated in the same manner as in Example 1.

### Example 8

Granulated particles for a cold storage material were manufactured in the same manner as in Example 1 except that Tb₂O₃ powder was used instead of the Gd₂O₃ powder. The manufactured granulated particles for a cold storage material were evaluated in the same manner as in Example 1.

### Example 9

Granulated particles for a cold storage material were manufactured in the same manner as in Example 1 except that Dy₂O₃ powder was used instead of the Gd₂O₃ powder. The manufactured granulated particles for a cold storage material were evaluated in the same manner as in Example 1.

### Example 10

Granulated particles for a cold storage material were manufactured in the same manner as in Example 1 except that Ho₂O₃ powder was used instead of the Gd₂O₃ powder. The manufactured granulated particles for a cold storage material were evaluated in the same manner as in Example 1.

### COMPARATIVE EXAMPLE

When cold storage particles of Comparative Example 1 were manufactured, defoaming was not performed, a calcium concentration of a gelling liquid was 0.5 mol %, and the gelling time was five hours as compared with the case of manufacturing the cold storage particles of Example 1. The manufactured granulated particles for a cold storage material were evaluated in the same manner as in Example 1.

The granulated particles for a cold storage material of the comparative example differ from the granulated particles for a cold storage material of Example 1 in that a percentage of the second void fraction of the outer circumferential portion and the first void fraction of the inner portion is higher than 101%. In other words, the granulated particles differ from the granulated particles for a cold storage material of Example 1 in that the second void fraction is higher than the first void fraction.

Regarding the granulated particles for a cold storage material of the examples and the comparative example, the first void fraction of the inner portion of the particle, the second void fraction of the outer circumferential portion of the particle, the percentage of the second void fraction to the first void fraction, and the degree of progress of sulfurization are provided in Table 1.

TABLE 1

| | | | | Second void | Degree of progress of | |
|---|---|---|---|---|---|---|
| | | | | fraction/ | sulfurization as compared | Breakage |
| | Raw material | First void | Second void | first void | with comparative example | ratio |
| | powder | fraction (%) | fraction (%) | fraction (%) | (%) | (wt %) |
| Example 1 | Gd2O3/Al2O3 | 30 | 7.5 | 0.25 | 100 | 0.01 |
| Example 2 | Gd2O3/Al2O3 | 30 | 25.5 | 85 | 100 | 2.9 |
| Example 3 | Gd2O3/Al2O3 | 30 | 22.5 | 75 | 100 | 0.9 |
| Example 4 | Gd2O3/Al2O3 | 30 | 3 | 10 | 100 | 0.05 |
| Example 5 | Gd2O3/Al2O3 | 30 | 0.3 | 1 | 100 | 0.02 |
| Example 6 | Gd2O3/Al2O3 | 30 | 0.042 | 0.14 | 99 | 0.01 |
| Example 7 | Gd2O3/Al2O3 | 30 | 0.0015 | 0.005 | 41 | 0.01 |
| Example 8 | Tb2O3/Al2O3 | 30 | 7.5 | 0.25 | 100 | 0.01 |
| Example 9 | Dy2O3/Al2O3 | 30 | 7.5 | 0.25 | 100 | 0.01 |
| Example 10 | Ho2O3/Al2O3 | 30 | 7.5 | 0.25 | 100 | 0.01 |
| Comparative | Gd2O3/Al2O3 | 30 | 30.3 | 101 | 100 | 3 |
| Example | | | | | | |

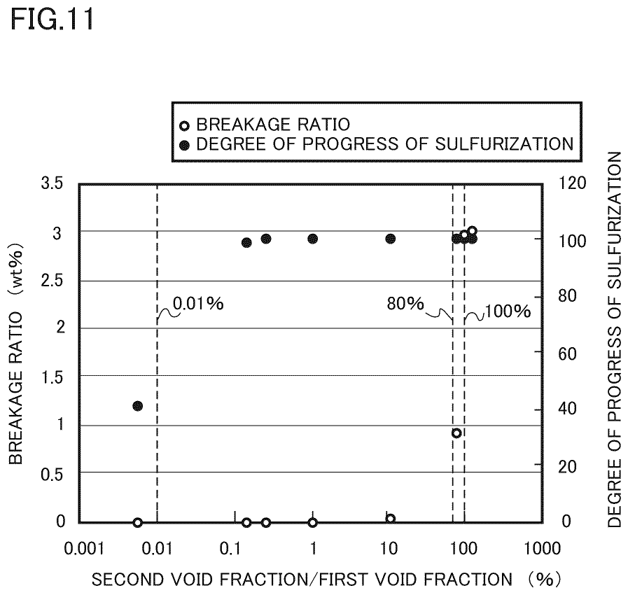

FIG. 11 is a graph illustrating evaluation results of the examples and the comparative example. FIG. 11 is a graph illustrating the breakage ratios and the degrees of progress of sulfurization of the granulated particles for cold storage particles of Examples 1 to 7 and the comparative example. The breakage ratios and the degrees of progress of sulfurization of the granulated particles for cold storage particles are illustrated with the percentage of the second void fraction to the first void fraction as a parameter.

The breakage ratio of the granulated particles for cold storage particles is indicated by white circles in FIG. 11. The degree of progress of sulfurization is indicated by black circles in FIG. 11.

As is clear from Table 1 and FIG. 1, when the second void fraction of the outer circumferential portion of the granulated particle for cold storage particles is smaller than the first void fraction of the inner portion thereof, the breakage ratio of the granulated particles for cold storage particles is reduced.

From the viewpoint of reducing the breakage ratio of the granulated particles for cold storage particles, the second void fraction is preferably equal to or lower than 80% of the first void fraction, more preferably equal to or lower than 20%, and still more preferably equal to or lower than 10%.

On the other hand, as is clear from Table 1 and FIG. 11, when the second void fraction of the outer circumferential portion of the granulated particle for cold storage particles is smaller than the first void fraction of the inner portion thereof, the degree of progress of sulfurization of the granulated particles for cold storage particles is reduced. The reason why the percentage of the second void fraction to the first void fraction is very decreased to decrease the degree of progress of sulfurization is considered to be that, when the outer circumferential portion of the particle becomes dense, the sulfidizing gas can be prevented from progressing to the inner portion of the particle.

From the viewpoint of improving the degree of progress of sulfurization of the granulated particle for cold storage particles, the second void fraction is preferably equal to or higher than 0.01% of the first void fraction, more preferably equal to or higher than 0.1%, and still more preferably equal to or higher than 1%.

Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. For example, a component of one embodiment may be replaced with or changed into a component of another embodiment. These embodiments and modifications thereof are included in the scope or gist of the invention and are included in the invention described in WHAT IS CLAIMED IS; and the scope of equivalents thereof.

Hereinafter, technical proposals of the present invention will be described. The following technical proposals are included in the scope of the present invention.

### (Technical Proposal 1)

A granulated particle for cold storage particles, including:
a first region having a first void fraction; and
a second region that is closer to an outer edge of the particle than the first region and has a second void fraction lower than the first void fraction.

### (Technical Proposal 2)

The granulated particle for cold storage particles according to Technical Proposal 1, in which the second region surrounds the first region.

### (Technical Proposal 3)

The granulated particle for cold storage particles according to Technical Proposal 1 or 2, in which the second void fraction is equal to or higher than 0.01% and equal to or lower than 80% of the first void fraction.

### (Technical Proposal 4)

The granulated particle for cold storage particles according to any one of Technical Proposals 1 to 3, in which the first void fraction is equal to or higher than 10% and equal to or lower than 50%, and the second void fraction is equal to or higher than 0% and lower than 10%.

### (Technical Proposal 5)

The granulated particle for cold storage particles according to any one of Technical Proposals 1 to 4, including: oxygen (O); and at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

### (Technical Proposal 6)

The granulated particle for cold storage particles according to any one of Technical Proposals 1 to 5, in which a distance of the second region from the outer edge toward the inner side of the particle is less than 20% of a particle size of the particle, and a distance of the first region from the outer edge toward the inner side of the particle is equal to or more than 15% of the particle size of the particle.

### (Technical Proposal 7)

The cold storage particle according to any one of Technical Proposals 1 to 6, in which a relative density is equal to or higher than 10% and equal to or lower than 50%.

### (Technical Proposal 8)

The cold storage particle according to any one of Technical Proposals 1 to 7, in which the granulated particle is a gel.

### (Technical Proposal 9)

The granulated particle for cold storage particles according to any one of Technical Proposals 1 to 8, further comprising a third region that is farther from the outer edge of the granulated particle than the first region and has a third void fraction lower than the first void fraction.

### (Technical Proposal 10)

The granulated particle for cold storage particles according to Technical Proposal 9, in which the second region surrounds the first region, and the first region surrounds the third region.

### (Technical Proposal 11)

Cold storage particles obtained by sintering the granulated particle for cold storage particles according to any one of Technical Proposals 1 to 10.

### (Technical Proposal 12)

The cold storage particles according to Technical Proposal 11, in which a maximum value of volumetric specific heat in a temperature range of 2 K or higher to 10 K or lower is equal to or larger than 0.5 J/(cm³·K).

### (Technical Proposal 13)

A regenerator filled with a plurality of the cold storage particles according to Technical Proposal 11 or 12.

### (Technical Proposal 14)

A refrigerator including the regenerator according to Technical Proposal 13.

### (Technical Proposal 15)

A cryopump including the refrigerator according to Technical Proposal 14.

### (Technical Proposal 16)

A superconducting magnet including the refrigerator according to Technical Proposal 14.

### (Technical Proposal 17)

A nuclear magnetic resonance imaging apparatus including the refrigerator according to Technical Proposal 14.

### (Technical Proposal 18)

A nuclear magnetic resonance apparatus including the refrigerator according to Technical Proposal 14.

### (Technical Proposal 19)

A magnetic field application-type single crystal pulling-out apparatus including the refrigerator according to Technical Proposal 14.

### (Technical Proposal 20)

A helium recondensing apparatus including the refrigerator according to Technical Proposal 14.

What is claimed is:

1. A granulated particle for cold storage particles, comprising:
a first region having a first void fraction; and
a second region that is closer to an outer edge of the particle than the first region and has a second void fraction lower than the first void fraction.

2. The granulated particle for cold storage particles according to claim 1, wherein the second region surrounds the first region.

3. The granulated particle for cold storage particles according to claim 1, wherein the second void fraction is equal to or higher than 0.01% and equal to or lower than 80% of the first void fraction.

4. The granulated particle for cold storage particles according to claim 1, wherein the first void fraction is equal to or higher than 10% and equal to or lower than 50%, and the second void fraction is equal to or higher than 0% and lower than 10%.

5. The granulated particle for cold storage particles according to claim 1, further comprising:
oxygen (O); and
at least one rare-earth element selected from the group consisting of yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

6. The granulated particle for cold storage particles according to claim 1, wherein a distance of the second region from the outer edge of the particle toward an inner side of the particle is less than 20% of a particle size of the particle, and a distance of the first region from the outer edge of the particle toward the inner side of the particle is equal to or more than 15% of the particle size of the particle.

7. The granulated particle for cold storage particles according to claim 1, wherein a relative density is equal to or higher than 10% and equal to or lower than 50%.

8. The granulated particle for cold storage particles according to claim 1, wherein the granulated particle is a gel.

9. The granulated particle for cold storage particles according to claim 1, further comprising a third region that is farther from the outer edge of the particle than the first region and has a third void fraction lower than the first void fraction.

10. The granulated particle for cold storage particles according to claim 9, wherein the second region surrounds the first region, and the first region surrounds the third region.

11. Cold storage particles obtained by sintering the granulated particle for cold storage particles according to claim 1.

12. The cold storage particles according to claim 11, wherein a maximum value of volumetric specific heat in a temperature range of 2 K or higher to 10 K or lower is equal to or larger than 0.5 J/(cm³·K).

13. A regenerator filled with a plurality of the cold storage particles according to claim 11.

14. A refrigerator comprising the regenerator according to claim 13.

15. A cryopump comprising the refrigerator according to claim 14.

16. A superconducting magnet comprising the refrigerator according to claim 14.

17. A nuclear magnetic resonance imaging apparatus comprising the refrigerator according to claim 14.

18. A nuclear magnetic resonance apparatus comprising the refrigerator according to claim 14.

19. A magnetic field application-type single crystal pulling-out apparatus comprising the refrigerator according to claim 14.

20. A helium recondensing apparatus comprising the refrigerator according to claim 14.
